(19) United States
(12) Patent Application Publication
(10) Pub. No.: US 2021/0105914 A1
(43) Pub. Date: Apr. 8, 2021

(54) MARINE ELECTRONIC DEVICE HEAT DISSIPATION SYSTEMS AND METHODS

(71) Applicant: Navico Holding AS, Egersund (NO)

(72) Inventor: Richard Bardsley, Auckland (NZ)

(21) Appl. No.: 16/594,286

(22) Filed: Oct. 7, 2019

(51) Int. Cl. H05K 7/20

(52) U.S. Cl. CPC H05K 7/20418

(57) ABSTRACT

Marine electronic device thermal transfer assemblies and methods of assembling same. A marine electronic device includes a first housing portion and a second housing portion, the second housing portion releasably coupled with the first housing portion to define an enclosed space therein. Marine electronics are disposed within the enclosed space and include at least one heat source component. The at least one heat source component is spaced apart from the second housing portion by a first distance. A substrate is disposed between the at least one heat source component and the second housing portion, and a graphite-based thermal transfer material is disposed between the at least one heat source component and the substrate and between the substrate and the second housing portion. The thermal transfer material defines a heat transfer path along the thermal transfer material from the at least one heat source component to the second housing portion.

### TECHNICAL FIELD

Embodiments of the present invention generally relate to the field of marine electronic devices. More particularly, certain embodiments of the present invention relate to systems and methods for improving thermal dissipation from electronic components of marine electronic devices.

### BACKGROUND

A variety of marine electronic devices, including multi-functional displays, sonar transducers, navigational displays, fishfinders, and autopilot devices, are known. Many marine electronic devices include electronic components, such as processors and various integrated circuits and chips, which generate heat during operation. It is necessary to dissipate the heat from such electronic components to ensure that they function properly, as excessive heat can damage various electronic components and damage the marine electronic device.

The foregoing discussion is intended only to illustrate various aspects of the related art in the field of the invention at the time, and should not be taken as a disavowal of claim scope.

### SUMMARY

It is known to employ a thermal interface pad to dissipate heat from an electronic component in an electronic device. Such pads, which generally comprise silicone and/or ceramic materials, may be placed on a heat source component to conduct heat from that component to a heat spreader or another heat sink. However, thermal interface pads typically have a thermal conductivity only of about one (1) to four (4) W/m-K. Thus, to be effective, such thermal interface pads are often optimum with a thickness of about one (1) mm, as they lose effectiveness with increasing thickness. Moreover, thermal interface pads are limited to practical thicknesses of about five (5) mm, and beyond five (5) mm such pads are generally not effective or available.

Where an electronic device includes a mechanical separation, and/or tolerance, or air gap, between a heat source component and a heat sink that is greater than five (5) mm, thermal interface pads typically cannot usefully transfer heat from the heat source component. Moreover, marine electronic devices are often subject to prolonged periods outside in the sun, which can make heat dissipation even a greater than normal challenge. While it is possible to redesign the case to include, for example, a heat-conductive metal post or pillar that bridges some of the air gap so that a thermal interface pad can be used, in practice doing so can be cost prohibitive and require extra work, such as sealing the interface between heat sink and case. Further, adding a metal post or pillar may interfere with the operation of certain other electronic components of the electronic device, such as a GPS antenna.

Accordingly, embodiments of the present invention provide a thermal transfer assembly that facilitates removal of heat from a heat source component of an electronic device, such as a marine electronic device. In certain embodiments, the thermal transfer assembly may comprise a substrate that is partially or completely wrapped with a thermally conductive material. In some embodiments, the substrate may be a suitable foam material, and the thermally conductive material may comprise a thermally conductive sheet comprising graphite. In various embodiments, the thermal transfer assembly provides for conduction of heat from a heat source component to a heat sink or other external case feature, such as a portion of a housing of a marine electronic device, across much greater distances or air gaps than prior art thermally conductive pads. In other words, in various embodiments, a heat conductive path is provided along or around a substrate, such as one or more foam blocks, from a heat source component to a heat sink or other external case feature. In various embodiments, the air gap or mechanical tolerance may be many times greater than the thickness of the thermally conductive material, but by providing a heat conductive path that may be substantially “in-plane” along a thermally conductive material that is wrapped around a substrate, effective heat transfer is possible over greater distances. In this regard, in-plane heat conduction refers to a direction within, or along, a planar surface of the thermally conductive material, as opposed to “through-plane” heat conduction, which refers to the direction perpendicular to the planar surface. For instance, in various embodiments, a thermal transfer assembly may effectively transfer heat over air gaps of about twenty-five (25) mm to thirty (30) mm, or greater distances.

Further, in various embodiments, the substrate may have a thickness that is equal to or greater than the mechanical tolerance or air gap across which heat must be transferred. Where the substrate has a greater thickness, it may be compressed, and pressure will be applied to the thermally conductive material so that it is pressed against the heat source component and the heat sink. This arrangement may ensure good contact between the thermally conductive material and the heat source component and between the thermally conductive material and the heat sink. Further, due to the compliance and/or compressibility of the substrate and the thermally conductive material in various embodiments, less precision is required for manufacture and assembly of electronic devices comprising this thermal transfer assembly. In other words, various embodiments may accommodate a very wide set of mechanical tolerances in assembly, including with respect to opposing heat source component and heat sink surfaces that are not well-aligned or parallel, and with respect to air gaps that are not defined in a uniform space. This may yield increases in efficiency and decrease production cost. Further, use of thermal transfer assemblies in accordance with embodiments of the present invention may eliminate the need to use metal heat sinks on portions of a marine electronic device housing, which may reduce not only cost, but also weight of the device.

According to one embodiment, a thermal transfer assembly for a marine electronic device comprises a substrate. The substrate has a top surface, a bottom surface, and at least one side surface extending between the top surface and the bottom surface, and the substrate comprises a foam material. The thermal transfer assembly also comprises a thermal transfer material comprising at least one layer, and the at least one layer comprises graphite. The thermal transfer material further comprises a first portion and a second portion spaced apart from the first portion. The first portion is coupled with the substrate top surface and the second portion is coupled with the substrate bottom surface. Also, the thermal transfer assembly comprises a thermally conductive path along the thermal transfer material between the first portion and the second portion.

In some embodiments, the thermal transfer material comprises at least one graphite sheet. Also, in some embodiments, the substrate defines a cuboid shape. Further, in an embodiment, the substrate comprises two foam blocks. In yet another example embodiment, the thermal transfer material is not connected with the at least one side surface of the substrate. In some embodiments, the substrate is wrapped with the thermal transfer material.

According to another embodiment, a marine electronic device comprises a housing, and the housing comprises a first housing portion and a second housing portion. The second housing portion is releasably coupled with the first housing portion to define an enclosed space therein. The marine electronic device also comprises marine electronics disposed within the enclosed space. The marine electronics are disposed on a circuit board and comprise at least one heat source component. The at least one heat source component is spaced apart from the second housing portion by a first distance. Further, the marine electronic device comprises a substrate disposed between the at least one heat source component and the second housing portion. The substrate comprises a first surface proximate the at least one heat source component and a second surface proximate the second housing portion. Additionally, the marine electronic device comprises a thermally-conductive path extending along a first thermal transfer material having a first portion and a second portion. The first portion is disposed between the first surface of the substrate and the at least one heat source component, and the second portion is disposed against an interior surface of the second housing portion.

In various example embodiments, the substrate is compressible, and the substrate defines a thickness that is greater than the first distance. In some embodiments, the substrate comprises a foam. Also, in another example embodiment, the marine electronic device further comprises a second thermal transfer material disposed on an interior surface of the second housing portion between the first thermal transfer material and the second housing portion. In some embodiments, the at least one heat source component comprises a processor. Further, in another example embodiment, the marine electronic device further comprises a heat spreader disposed between the at least one heat source component and the first portion of the first thermal transfer material. In yet another example, the second portion of the first thermal transfer material is coupled with the second surface of the substrate. Additionally, in some examples, the first thermal transfer material comprises graphite.

According to a still further example embodiment, a method of assembling a marine electronic device comprises the steps of providing a housing, the housing comprising a first housing portion and a second housing portion, and coupling marine electronics with the first housing portion. The marine electronics comprise at least one heat source component. The method of assembling a marine electronic device further comprises the steps of providing a substrate, the substrate having a first end and a second end opposite the first end, and wrapping the substrate with a thermal transfer material such that the thermal transfer material extends between the first and second ends of the substrate. Additionally, the method of assembling a marine electronic device comprises the steps of disposing the first end of the wrapped substrate proximate the at least one heat source component and coupling the second housing portion with the first housing portion such that the second end of the substrate is proximate an interior surface of the second housing portion.

In some embodiments, the method of assembling a marine electronic device further comprises the step of applying pressure to the thermal transfer material to hold it in place against the heat source component and the interior surface of the second housing portion. In one example, the thermal transfer material is coupled with the first and second ends of the substrate via an adhesive. Also, in another example, the substrate comprises a body extending between the first and second ends of the substrate, and the thermal transfer material is not adhered to the body. In various embodiments, the thermal transfer material has an in-plane thermal conductivity greater than about 100 W/m-K. In still further embodiments, the step of wrapping the substrate with a thermal transfer material further comprises the step of coupling at least two sheets of thermal transfer material together.

### BRIEF DESCRIPTION OF THE DRAWINGS

Having thus described some example embodiments in general terms, reference will now be made to the accompanying drawings, which are not necessarily drawn to scale, and wherein:

FIGS. 1-2 are perspective views of exemplary marine electronic devices with which embodiments of the present invention may be used;

FIG. 3 is a block diagram of an example marine electronic system, in accordance with some example embodiments discussed herein;

FIGS. 4A-4B are top and bottom side perspective views of an example thermal transfer assembly in accordance with an embodiment of the present invention;

FIG. 5 is a schematic cross-sectional view of an example graphite material with which embodiments of the present invention may be used;

FIG. 6 is a side view of an example thermal transfer assembly in compression in accordance with an embodiment of the present invention;

FIG. 7 is a schematic cross-sectional view of an example marine electronic device comprising a thermal transfer assembly in accordance with an embodiment of the present invention;

FIG. 8 is a schematic partial cross-sectional view of a portion of an example marine electronic device comprising a thermal transfer assembly in accordance with another embodiment of the present invention;

FIG. 9 is a detail plan view of the thermal transfer assembly of FIG. 8 disposed on a heat spreader of a marine electronic device in accordance with an embodiment of the present invention;

FIG. 10 is a detail plan view of the thermal transfer assembly of FIG. 8 disposed on a rear housing of the marine electronic device of FIG. 9 in accordance with an embodiment of the present invention;

FIG. 11 is a detail plan view of a rear housing of a marine electronic device in accordance with another embodiment of the present invention;

FIG. 12 is a detail plan view of a front housing of the marine electronic device of FIG. 11 wherein a thermal transfer assembly is disposed on a heat source component of the marine electronic device;

FIG. 13 is a partial cross-sectional view of the marine electronic device of FIGS. 11-12 wherein the front and rear housing portions are coupled together;

FIG. 14 is a schematic partial cross-sectional view of a portion of an example marine electronic device comprising a thermal transfer assembly according to another embodiment of the present invention;

FIG. 15 is a plan view of the thermal transfer assembly of FIG. 14 disposed in a portion of a housing of the marine electronic device;

FIG. 16 is a perspective view of another portion of the housing of the marine electronic device of FIG. 14 showing certain electronic components thereof;

FIG. 17 is a detail perspective view of the substrate of the thermal transfer assembly of FIG. 14;

FIG. 18 is a plan view of the thermal transfer material of the thermal transfer assembly of FIG. 14;

FIG. 19 is a partial cross sectional view of the marine electronic device of FIG. 14; and

FIG. 20 is a flowchart of an example method of assembling a marine electronic device in accordance with an embodiment of the present invention.

Repeat use of reference characters in the present specification and drawings is intended to represent same or analogous features or elements of embodiments of the present invention.

### DETAILED DESCRIPTION OF PREFERRED EMBODIMENTS

Reference will now be made in detail to presently preferred embodiments of the invention, one or more examples of which are illustrated in the accompanying drawings. Each example is provided by way of explanation of the invention, not limitation of the invention. In fact, it will be apparent to those skilled in the art that modifications and variations can be made in the present invention without departing from the scope or spirit thereof. For instance, features illustrated or described as part of one embodiment may be used on another embodiment to yield a still further embodiment. Thus, it is intended that the present invention covers such modifications and variations as come within the scope of the appended claims and their equivalents.

Further, either of the terms “or” and “one of ______ and ______,” as used in this disclosure and the appended claims is intended to mean an inclusive “or” rather than an exclusive “or.” That is, unless specified otherwise, or clear from the context, either of the phrases “X employs A or B” and “X employs one of A and B” is intended to mean any of the natural inclusive permutations. That is, either phrase is satisfied by any of the following instances: X employs A; X employs B; or X employs both A and B, regardless whether the phrases “at least one of A or B” or “at least one of A and B” are otherwise utilized in the specification or claims. In addition, the articles “a” and “an” as used in this application and the appended claims should generally be construed to mean “one or more” unless specified otherwise or clear from the context to be directed to a singular form. Throughout the specification and claims, the following terms take at least the meanings explicitly associated herein, unless the context dictates otherwise. The meanings identified below do not necessarily limit the terms, but merely provide illustrative examples for the terms. The meaning of “a,” “an,” and “the” may include plural references, and the meaning of “in” may include “in” and “on.” The phrase “in one embodiment,” as used herein does not necessarily refer to the same embodiment, although it may.

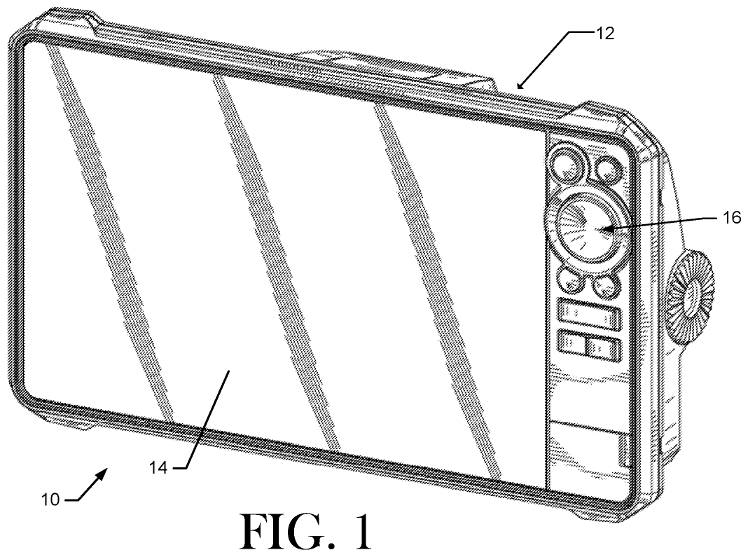

As noted above, embodiments of the present invention comprise apparatus and methods for dissipating heat from heat source components in a marine electronic device. Certain non-limiting examples of marine electronic devices with which embodiments of the present invention may be used are discussed with reference to FIGS. 1-3 below.

FIG. 1 is a perspective view of a multi-functional display (“MFD”) 10. MFD 10 comprises a housing 12 and a user interface, which may include at least one display 14. The display 14, e.g., screen, may be configured to display images and may be configured to receive input from a user. Display 14 may be, for example, a conventional LCD (liquid crystal display), a touch screen display or any other suitable display known in the art upon which images may be displayed. The user interface may also include one or more buttons 16 operative to receive user input by pressing or deflecting of the buttons 16.

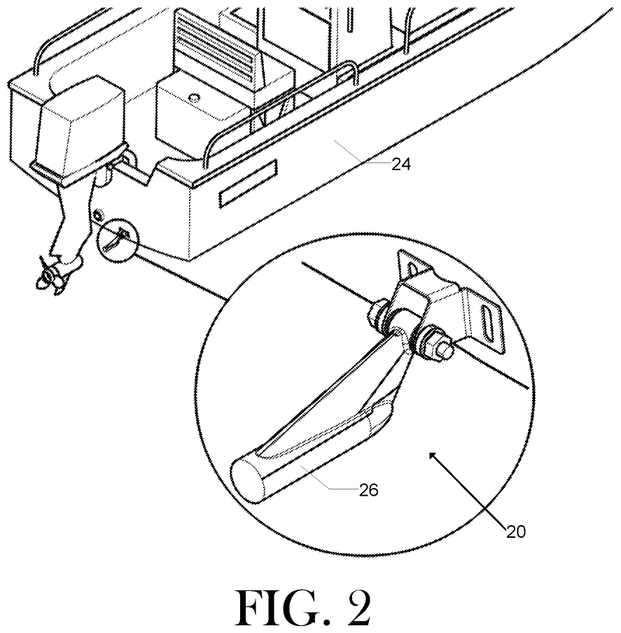

FIG. 2 is a perspective view of a sonar transducer assembly 20, which is another example of a marine electronic device with which embodiments of the present invention may be used. Sonar transducer assembly 20, which comprises a housing 26, may be mounted in various positions and to various portions of a vessel 24 and/or equipment associated with the vessel 24. For example, sonar transducer assembly 20 may be mounted to the transom of vessel 24 (as shown in FIG. 2), or the bottom or side of the hull of vessel 24, and/or to a trolling motor associated with the vessel 24, among other locations. As is well understood, transducer assembly 20 may include one or more transducer elements configured to transmit sound waves into a body of water, receive sonar return signals from the body of water, and convert the sonar return signals into sonar return data. The sonar return data may be displayed on a suitable device, such as the MFD 10 in FIG. 1.

Although some preferred embodiments are discussed below in the context of an MFD and a sonar transducer assembly, those of skill in the art will appreciate that the present invention is not so limited. In particular, it is contemplated that embodiments of the present invention may be used with any suitable electronic device, including but not limited to marine electronic devices. Marine electronic devices with which embodiments of the present invention may be used include, but are not limited to, MFDs, sonar transducer assemblies, sonar processor modules, fishfinders, autopilots, GPS antennas, and/or any other marine electronic device having electrical systems and components that require heat dissipation.

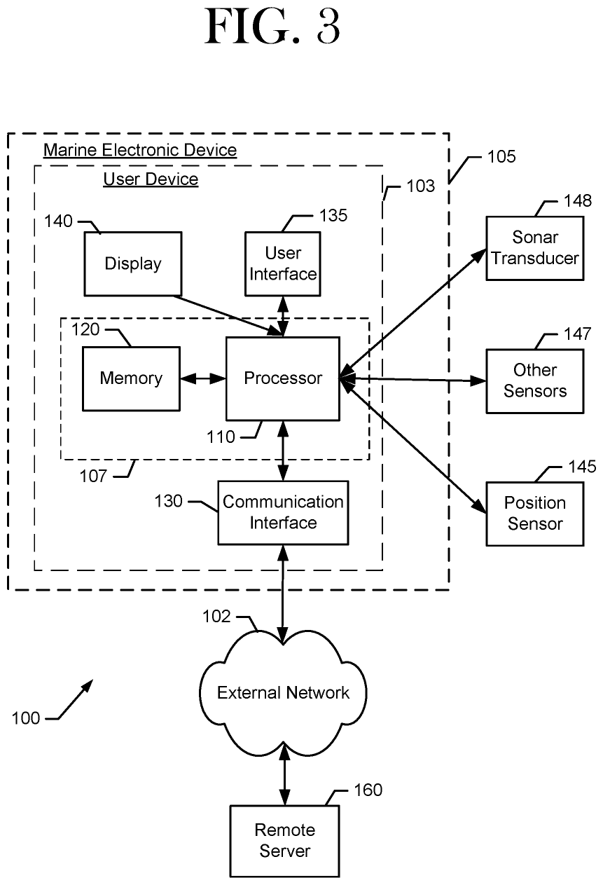

Thus, for instance, marine electronic devices with which embodiments of the present invention may be used may be part of and/or operate within a marine electronic system 100, as shown in FIG. 3. In this regard, FIG. 3 shows a block diagram of an example computing device, such as user device 103. The depicted computing device is an example marine electronic device 105. The marine electronic device 105 may include a number of different modules or components, each of which may comprise any device or means embodied in either hardware, software, or a combination of hardware and software configured to perform one or more corresponding functions. The marine electronic device may also be in communication with a network 102.

The marine electronic device 105 may also include one or more communications modules configured to communicate with one another in any of a number of different manners including, for example, via a network. In this regard, the communications module may include any of a number of different communication backbones or frameworks including, for example, Ethernet, the NMEA 2000 framework, GPS, cellular, WiFi, or other suitable networks. The network may also support other data sources, including GPS, autopilot, engine data, compass, radar, etc. Numerous other peripheral devices such as one or more wired or wireless multi-function displays may be included in marine electronic system 100.

The marine electronic device 105 may include a processor 110, a memory 120, a user interface 135, a display 140, and a communication interface 130. Additionally, the marine electronic device 105 may include or otherwise be in communication with one or more sensors (e.g. position sensor 145, other sensors 147, etc.) and/or one or more sonar transducers 148.

The processor 110 may by any means be configured to execute various programmed operations or instructions stored in a memory device such as a device or circuitry operating in accordance with software or otherwise embodied in hardware or a combination of hardware and software (e.g. a processor operating under software control or the processor embodied as an application specific integrated circuit (ASIC) or field programmable gate array (FPGA) specifically configured to perform the operations described herein, or a combination thereof) thereby configuring the device or circuitry to perform the corresponding functions of the processor 110 as described herein. In this regard, the processor 110 may be configured to analyze electrical signals communicated thereto to provide or receive sonar data, sensor data, location data, and/or additional environmental data. For example, the processor 110 may be configured to receive sonar return data, generate sonar image data, and generate one or more sonar images based on the sonar image data. Additionally, the processor may be configured to present a nautical chart correlated to the sonar images and/or shift/modify the perspective of the sonar image and nautical chart in response to a user input.

In some embodiments, the processor 110 may be further configured to implement signal processing or enhancement features to improve the display characteristics or data or images, collect or process additional data, such as time, temperature, GPS information, waypoint designations, or others, or may filter extraneous data to better analyze the collected data. It may further implement notices and alarms, such as those determined or adjusted by a user, to reflect depth, presence of fish, proximity of other vehicles, e.g. watercraft, etc.

In an example embodiment, the memory 120 may include one or more non-transitory storage or memory devices such as, for example, volatile and/or non-volatile memory that may be either fixed or removable. The memory 120 may be configured to store instructions, computer program code, marine data, such as sonar data, chart data, location/position data, and other data associated with the navigation system in a non-transitory computer readable medium for use, such as by the processor for enabling the marine electronic device 105 to carry out various functions in accordance with example embodiments of the present invention. For example, the memory 120 could be configured to buffer input data for processing by the processor 110. Additionally or alternatively, the memory 120 could be configured to store instructions for execution by the processor 110.

The communication interface 130 may be configured to enable connection to external systems (e.g. an external network 102). In this manner, the marine electronic device 105 may retrieve stored data from a remote server 160 via the external network 102 in addition to or as an alternative to the onboard memory 120. Additionally or alternatively, the marine electronic device may transmit or receive data, such as sonar signals, sonar returns, sonar image data or the like to or from a sonar transducer 148. In some embodiments, the marine electronic device may also be configured to communicate with a propulsion system of a vessel. The marine electronic device may receive data indicative of operation of the propulsion system, such as engine or trolling motor running, running speed, or the like.

The position sensor 145 may be configured to determine the current position and/or location of the marine electronic device 105. For example, the position sensor 145 may comprise a GPS, bottom contour, inertial navigation system, such as machined electromagnetic sensor (MEMS), a ring laser gyroscope, or other location detection system.

The display 140, e.g. screen, may be configured to display images and may include or otherwise be in communication with a user interface 135 configured to receive input from a user. The display 140 may be, for example, a conventional LCD (liquid crystal display), a touch screen display, mobile device, or any other suitable display known in the art upon which images may be displayed.

In any of the embodiments, the display 140 may present one or more sets of marine data (or images generated from the one or more sets of data). Such marine data includes chart data, radar data, weather data, location data, position data, orientation data, sonar data, or any other type of information relevant to a watercraft. In some embodiments, the display 140 may be configured to present such marine data simultaneously as one or more layers or in split-screen mode. In some embodiments, a user may select any of the possible combinations of the marine data for display.

In some further embodiments, various sets of data, referred to above, may be superimposed or overlaid onto one another. For example, a route may be applied to (or overlaid onto) a chart (e.g. a map or navigational chart). Additionally or alternatively, depth information, weather information, radar information, sonar information, or any other navigation system inputs may be applied to one another.

The user interface 135 may include, for example, a keyboard, keypad, function keys, mouse, scrolling device, input/output ports, touch screen, or any other mechanism by which a user may interface with the system.

Although the display 140 of FIG. 3 is shown as being directly connected to the processor 110 and within the marine electronic device 105, the display 140 could alternatively be remote from the processor 110 and/or marine electronic device 105. Likewise, in some embodiments, the position sensor 145 and/or user interface 135 could be remote from the marine electronic device 105.

The marine electronic device 105 may include and/or be in communication with one or more other sensors 147 configured to measure environmental conditions. The other sensors 147 may include, for example, an air temperature sensor, a water temperature sensor, a current sensor, a light sensor, a wind sensor, a speed sensor, or the like.

The sonar transducer 148 may be housed in a trolling motor housing, attached to a vessel or, in some cases, be castable or otherwise remote. The sonar transducer 148 may be configured to gather sonar return signals, e.g. sonar returns, from the underwater environment relative to the vessel. Accordingly, the processor 110 may be configured to receive the sonar return data from the sonar transducer 148, process the sonar return data to generate an image including a sonar image based on the gathered sonar return data. In some embodiments, the marine electronic device 105 may be used to determine depth and bottom contours, detect fish, locate wreckage, etc. In this regard, sonar beams or pulses from a sonar transducer 148 can be transmitted into the underwater environment. The sonar signals reflect off objects in the underwater environment (e.g. fish, structure, sea floor bottom, etc.) and return to the transducer assembly, which converts the sonar returns into sonar return data that can be used to produce a sonar image of the underwater environment.

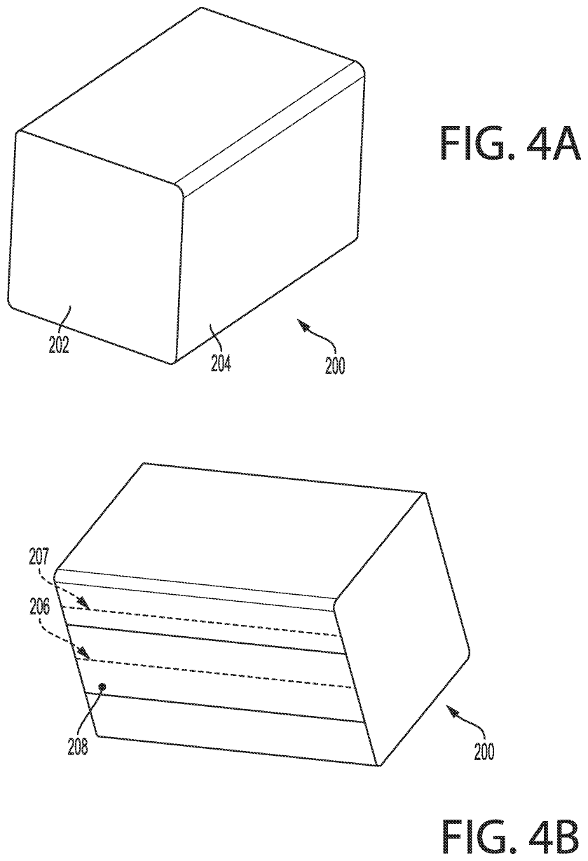

According to various embodiments, a thermal transfer assembly may be used with a marine electronic device to dissipate heat from a heat source component of the marine electronic device. In some embodiments, the thermal transfer assembly may be disposed within a housing of a marine electronic device during assembly thereof and disposed between a heat source component and a portion of the housing. Thereby, heat generated by the heat source component during operation may be transferred to the exterior of the housing. Some examples of thermal transfer assemblies within the scope of the present invention are discussed with reference to FIGS. 4A, 4B, 5, and 6.

In this regard, FIGS. 4A and 4B are perspective views of a thermal transfer assembly 200. As shown, thermal transfer assembly 200 may comprise a substrate 202 and a thermal transfer material 204. Substrate 202 may comprise a variety of lightweight, compliant materials in accordance with embodiments of the present invention. Substrate 202 preferably is suitable for providing mechanical support to maintain thermal transfer material 204 in position. Substrate 202 preferably is suitable for use within and, in some embodiments, compression by, a housing of a marine electronic device. Additionally, substrate 202 preferably is rated for use at temperatures greater than those generated by the heat source component from which heat is to be dissipated. Further, substrate 202 preferably is selected such that, in use, it does not apply or transfer excessive force to the heat source component. Those of skill in the art can select from a variety of materials for this purpose. Moreover, in some embodiments, thermal transfer assembly 200 may comprise a gap feature, wherein at least a portion of substrate 202 is not provided.

In one preferred embodiment, substrate 202 is a foam. As used herein, the term “foam” refers to any open-cell and closed-cell solid object including a dispersion of gas pockets or bubbles, whether discrete and separate or interconnected. While standard foams may be rated for temperatures of about 98 degrees Celsius, certain foams, such as silicone foams, may be rated for use at temperatures up to about 300 degrees Celsius. Some electronic components may run at temperatures exceeding 100 degrees Celsius. Accordingly, in one embodiment, substrate 202 may comprise a silicone foam, such as BF1000 X-soft silicone foam. In other embodiments, substrate 202 may comprise a lightweight rubber material, such as polyurethane rubber.

Substrate 202, as shown, is cuboid in shape, but that is not required. In various embodiments, substrate 202 may be of any suitable shape for taking up mechanical tolerances or air gaps within an electronic device. Thus, for example, substrate 202 may be spherical, half-spherical, frustoconical, or cylindrical, among other shapes in various embodiments. Those of skill in the art will appreciate that the dimensions and shape of substrate 202 may vary as needed or required for a particular air gap or mechanical tolerance in an electronic device. Similarly, substrate 202 need not comprise a single piece or component, but rather could comprise a plurality of substrate 202 components. For instance, four smaller foam blocks could be combined to define a single, larger foam block.

As discussed in more detail herein, in various embodiments, the thermal transfer material 204 may be disposed on and/or partially or completely wrapped around substrate 202. As used herein, the term “thermal transfer material” refers to thin, flexible or compliant natural or synthetic materials having a high thermal conductivity. For instance, thermal transfer materials used in various embodiments of the present invention may have a thermal conductivity equal to or greater than 100 W/m-K and up to or exceeding about 1900 W/m-K. Additionally, thermal transfer materials as used herein preferably are rated for use at temperatures greater than the temperatures that the heat source components reach during operation. For instance, preferably thermal transfer materials are rated for use at temperatures about or exceeding 120 degrees Celsius. Examples of suitable thermal transfer materials for use in various embodiments of the present invention comprise, but are not limited to, graphite sheets and thin films or foils of various metals, such as copper. Where the thermal transfer material comprises a graphite sheet, the thermal conductivity described above may be “in plane” and may be between about 1400 W/m-k and 1600 W/m-K. In other words, these materials have such conductivity along a plane in which a portion of the material lies, but not necessarily in a direction perpendicular to such plane. Of course, other embodiments may employ a thermal transfer material that is isotropic. This may be the case with a thermal transfer material comprising a copper foil. Where metallic films or foils are used in various embodiments, those of skill in the art will appreciate that they may be laminated.

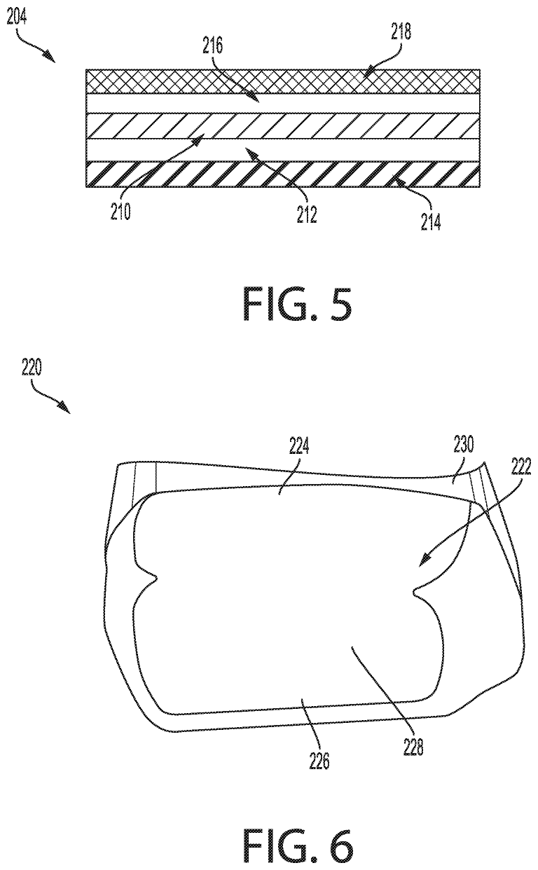

For example, in the illustrated embodiment, thermal transfer material 204 comprises a graphite sheet. The graphite sheet may be a synthetic crystalline carbon-based graphite sheet in some embodiments, and it may comprise a plurality of layers (see, e.g., FIG. 5). One example of a suitable graphite sheet may be the Tgon™ 9000 line of graphite sheets offered by Laird, though other materials may also be used. Another suitable graphite sheet may be a pyrolytic graphite sheet, such as those offered by various manufacturers. Such graphite sheets are sometimes referred to as graphene sheets.

Thermal transfer materials 204 within the scope of the present invention may have a variety of suitable thicknesses, depending among other things on the type of material used and the specific implementation in which it may be used. Where a graphite sheet is used as thermal transfer material 204, it may have a thickness between about 17 micrometers and about 100 micrometers, though the graphite sheet may be thicker than 100 micrometers in some example embodiments. In some exemplary embodiments, thermal transfer material 204 may have a thickness between about 40 micrometers and about 70 micrometers. In one exemplary embodiment, thermal transfer material 204 has a thickness of about 70 micrometers.

In the illustrated embodiment of FIGS. 4A and 4B, thermal transfer material 204 comprises a continuous graphite sheet that is wrapped around four adjoining faces of substrate 202. Although thermal transfer material 204 may cover the entirety of a substrate in some embodiments (e.g., including all six faces of substrate 202), that is not required. Indeed, in some embodiments, thermal transfer material 204 may be in contact with one, two, or three faces of substrate 202, or only certain portions of a differently-shaped substrate. Also, in various embodiments, thermal transfer material 204 need not comprise a single, continuous sheet, but rather may comprise more than one sheet. Where that is the case, it is preferred that each sheet of thermal transfer material 204 be arranged to at least partially overlap with another sheet so as to form a continuous pathway for heat to travel therealong.

As seen in FIG. 4B, the length of thermal transfer material 204 is selected in this embodiment such that an edge 206 of thermal transfer material 204 overlaps the opposing edge 207 thereof when thermal transfer material 204 is wrapped around substrate 202. A layer of suitable adhesive 208 may be applied over edge 206 to secure thermal transfer assembly 200 in place (e.g., on a heat source component) during assembly of a marine electronic device. Thus, the side of thermal transfer assembly 200 to which adhesive 208 is applied in FIG. 4B may be in contact with a heat source component during use. In one embodiment, adhesive 208 may be analogous to the 9415 low tack adhesive offered by 3M. Also, as discussed below, suitable adhesive may also be used to secure one or more portions of thermal transfer material 204 to substrate 202.

It will be appreciated, however, that neither this overlapping arrangement nor adhesive 208 are required in all embodiments. Indeed, in some embodiments, the length of thermal transfer material 204 may be selected such that, when thermal transfer material 204 is wrapped around substrate 202, edges 206 and 207 are adjacent to one another and/or are not overlapping.

In the illustrated embodiment, thermal transfer material 204 is wrapped only a single time around substrate 202, but that is not required. In some embodiments, thermal transfer material 204 may be wrapped a plurality of times around substrate 204. For example, where it is required that substrate 202 have a larger height due to the presence of a larger air gap, then it may be desirable in some embodiments to wrap substrate 202 with thermal transfer material 204 two or more times in order to compensate for the distance across which heat must be transferred. In general, those of skill in the art will appreciate that the dimensions selected for and configuration or implementation of thermal transfer material 204 may depend on various factors, including the temperature at which the heat source component will operate, the amount of heat dissipation required, etc.

Although in the illustrated embodiment thermal transfer material 204 is shown in direct contact with substrate 202, those of skill in the art will also appreciate that that is not required in all embodiments. For example, one or more intermediate materials, such as spacer elements, may be provided between thermal transfer material 204 and substrate 202, or between multiple substrate 202 elements or layers of substrate 202. Such intermediate materials need not be the same material as substrate 202.

Also, in various embodiments thermal transfer material 204 may comprise one or more layers. For example, in some embodiments, thermal transfer material 204 and/or thermal transfer assembly 200 may comprise multiple graphite layers. In some embodiments, thermal transfer material 204 could be a single layer, e.g., of synthetic or natural graphite or another suitable material. In other embodiments, and as shown for example in FIG. 5, thermal transfer material 204 may comprise a plurality of layers of different materials. In this regard, and in one example, thermal transfer material 204 may comprise a graphite sheet 210. A layer 212 of adhesive may be disposed beneath graphite sheet 210 in order to attach thermal transfer material 204 to an object, and a separating film 214 may protect the adhesive layer 212 until it is desired that the adhesive layer 212 be exposed. A protective layer may be provided above graphite sheet 210 and may comprise a layer 216 of polyethylene terephthalate (PET). Further, a separating protective backing paper or layer 218 (e.g., for protection during handling) may be disposed over PET layer 216.

It will be appreciated, of course, that other layer configurations are contemplated and within the scope of other embodiments. For instance, in some embodiments, there may be adhesive layers both above and below the graphite sheet. Also, in some embodiments, more than one graphite sheet may be provided.

As suggested above, in various embodiments, thermal transfer material 204 may be coupled with substrate 202 in a variety of ways. For example, in some embodiments, suitable adhesive may be used to couple thermal transfer material 204 with substrate 202. In this regard, suitable adhesive may be applied, for example during assembly, either to the substrate 202 or the substrate-facing side of thermal transfer material 204, or both. One example of a suitable adhesive is the 9415 low tack adhesive offered by 3M, but other adhesives may be used depending on the materials used for substrate 202 and thermal transfer material 204, the necessary or desired temperature rating of the thermal transfer assembly 200, and ease of assembly. As noted above, the thermal transfer material may also comprise an adhesive layer.

Preferably, the adhesive that is used to secure thermal transfer material 204 to substrate 202 is applied only between the thermal transfer material 204 and the substrate 202 at the portion(s) of thermal transfer assembly 200 that are adjacent the heat source component and/or the heat sink. For example, and with further reference to FIG. 6, a thermal transfer assembly 220 may comprise a substrate 222 having a first end 224, a second end 226, and a body 228 extending between the first end 224 and the second end 226. Substrate 222 in this embodiment is wrapped with a graphite-based thermal transfer material 230. During assembly of thermal transfer assembly 220, adhesive may be provided on substrate first end 224 and/or substrate second end 226 such that substrate 222 is connected with thermal transfer material 230 at either or both of the first and second ends 224, 226 of substrate 222. (Of course, as noted above, in other embodiments, adhesive may be provided on either or both portions of thermal transfer material 230 that are to be connected with substrate 222 first and second ends 224, 226.) However, adhesive preferably is not provided on any portion of body 228 (or on portions of the thermal transfer material 230 that may contact body 228) which is not in direct contact with the heat source component or the heat sink. Thereby, thermal transfer material is not connected with, and may move or flex relative to body 228. This is to allow free movement of material 230.

In use, thermal transfer assembly 220 may be disposed within a marine electronic device, e.g., in an air gap or mechanical tolerance, such that substrate first end 224 is proximate a heat sink, such as a portion of a housing of the electronic device, and substrate second end 226 is proximate the heat source component. The portion of thermal transfer material 230 coupled with substrate first end 224 may be in contact with the heat sink, and the portion of thermal transfer material 230 coupled with substrate second end 226 may be in contact with the heat source component. In some embodiments, the height of substrate 222 may be greater than the height of the air gap (e.g., the distance between the heat source component and a portion of the housing), such that the thermal transfer assembly 220 is placed in compression (e.g., between the heat source component and the housing portion). As shown in FIG. 6, this may cause deformation of body 228 of substrate 222. But, because thermal transfer material 230 is not adhered or otherwise connected to body 228, and due to the compliance and flexibility of thermal transfer material 230, compression of thermal transfer assembly 220 may cause the portions of thermal transfer material 230 that were adjacent body 228 during assembly to bow or flex outward away from body 228 in use. This is desirable because it may prevent damage to thermal transfer material 230, e.g., by crinkling or sharply bending, that would otherwise be caused if thermal transfer material 230 were adhered or otherwise connected with body 228, yet it still allows effective heat transfer along thermal transfer material 230. Those of skill in the art will appreciate that if, for example, a graphite sheet were used as thermal transfer material 230, then such crinkling or sharp bending may damage the structure of the graphite sheet and potentially reduce its thermal conductivity. Further, in such embodiments, compression of substrate 222 causes pressure to be applied to the thermal transfer material 230 such that it is maintained in good contact with the heat source component and the housing portion.

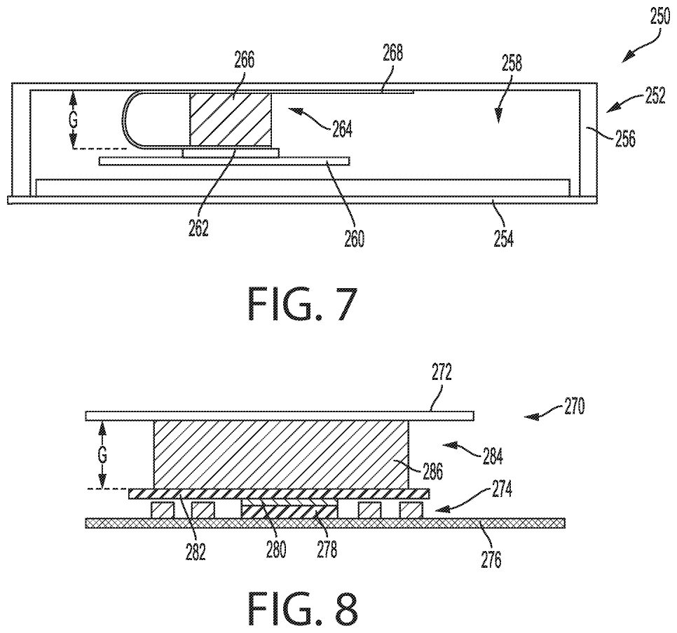

Certain exemplary embodiments of marine electronic devices comprising thermal transfer assemblies are discussed below with reference to FIGS. 7-19. Turning first to FIG. 7, a marine electronic device 250 is shown in schematic cross-section. Marine electronic device 250 comprises a housing 252 having a first housing portion 254 (e.g., a front housing) and a second housing portion 256 (e.g., a rear housing). First housing portion 254 and second housing portion 256 are shown coupled together to define an enclosed space 258. As shown, various electronic components are disposed within enclosed space 258, for example on a circuit board 260. One or more of the electronic components may be heat source components. As used herein, the term “heat source component” refers to any component of an electronic device that generates heat during operation, including but not limited to integrated circuits, microprocessors, and graphics cards, among others. In this example, marine electronic device 250 comprises a heat source component in the form of a processor 262 that is disposed on circuit board 260. An air gap G is defined between the processor 262 and the second housing portion 256. In this embodiment, marine electronic device 250 may be an MFD or another marine display device.

Marine electronic device 250 also comprises a thermal transfer assembly 264. Thermal transfer assembly 264 comprises a substrate 266 and a thermal transfer material 268. Substrate 266 is disposed in air gap G between processor 262 and second housing portion 256. In the illustrated embodiment, thermal transfer material 268 is not completely wrapped around substrate 266. Rather, as shown, one portion of thermal transfer material 268 is disposed between processor 262 and substrate 266, and another portion of thermal transfer material 268 is disposed between substrate 266 and second housing portion 268. Thermal transfer assembly 268 is folded around substrate 266, thereby providing a thermally conductive path between processor 262 and second housing portion 268. In some embodiments, the portions of thermal transfer material 268 in contact with processor 262 and/or housing portion 268 may be connected therewith using a suitable adhesive. One example of a suitable adhesive for this purpose may be the 468 adhesive transfer tape offered by 3M, though other adhesives may be used. Also in this embodiment, the portion of thermal transfer material 268 in contact with second housing portion 256 is larger than the top surface of substrate 266. As those of skill in the art will appreciate, increasing the area of thermal transfer material 268 in contact with the heat sink will increase the amount of heat transferred from processor 262.

FIG. 8 is a schematic cross-sectional view of a portion of a marine electronic device 270 in accordance with another embodiment of the present invention. As shown, marine electronic device 270 comprises a housing having a first housing portion (not shown) and a second housing portion 272. The housing defines an enclosed space in which various electronic components 274 are coupled with at least one circuit board 276. In this embodiment, a processor 278 is disposed on circuit board 276, and a thermal interface pad 280 is disposed on processor 278. As will be understood, thermal interface pad 280 may transfer heat from processor 278 to a heat spreader (in this instance, a flat aluminium plate) 282 disposed on thermal interface pad 280. Again, an air gap G is defined between heat spreader 282 and second housing portion 272.

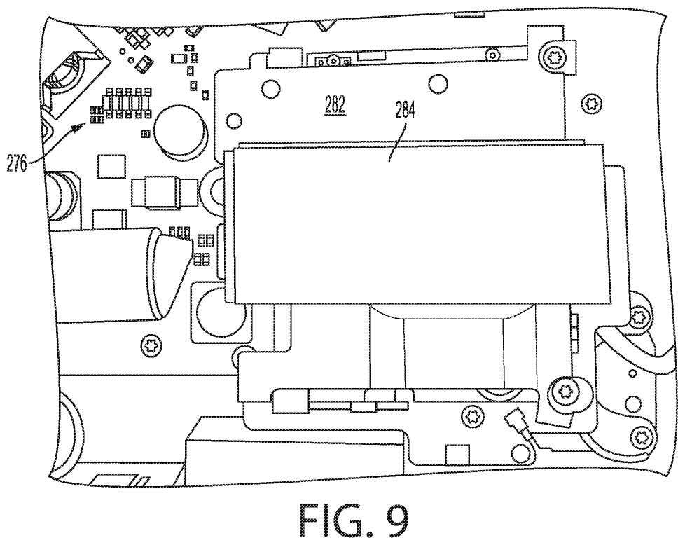

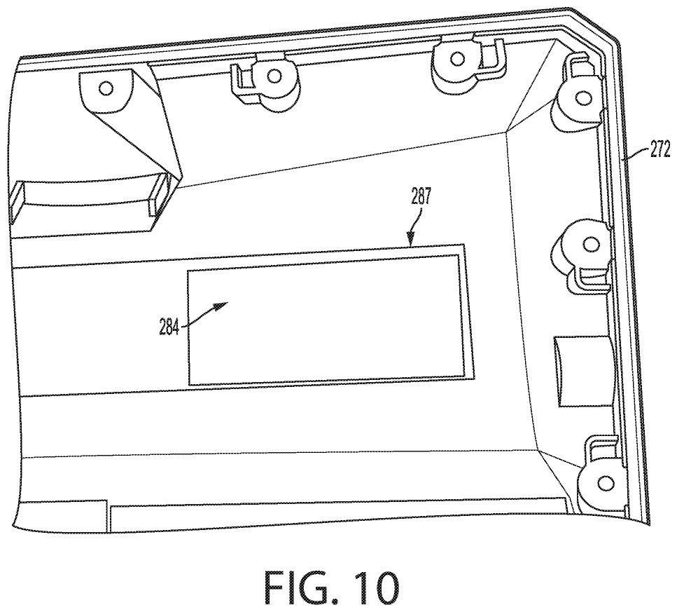

A thermal transfer assembly 284 is disposed between heat spreader 282 and second housing portion 272. In the illustrated embodiment, thermal transfer assembly 284 preferably is analogous to thermal transfer assembly 200, described above. Thus, thermal transfer assembly 284 may comprise a substrate (not shown) around which a thermal transfer material 286 is wrapped. Thermal transfer material 286 thereby completes a thermally conductive path from processor 278 to second housing portion 272 (including thermal interface pad 280 and heat spreader 282). FIG. 9 is a detail plan view of thermal transfer assembly 284 disposed on heat spreader 282, and FIG. 10 is a detail plan view of thermal transfer assembly 284 disposed on second housing portion 272. As noted above, in various embodiments, thermal transfer assembly 284 may be coupled with either or both of heat spreader 282 and/or second housing portion 272 via a suitable adhesive to facilitate assembly. As can be seen in FIG. 10, in one embodiment, a metal plate 287 may be disposed on or formed as part of second housing portion 272 and operate as a heat sink, though this is not required. Thermal transfer assembly 284 may be disposed on metal plate 287. Thus, in the embodiment shown in FIG. 10, thermal transfer assembly 284 may be disposed between the heat spreader 282 and metal plate 287 of second housing portion 272.

In embodiments analogous to that described with reference to FIGS. 8-10, performance characteristics demonstrate several advantages over the prior art. In one example, the substrate has dimensions of about 25 mm×25 mm×40 mm, and thermal transfer material 286 is a graphite sheet having a thickness of 70 micrometers. The processor 278 generates 4.1 W during operation. Notably, thermal transfer assembly 284 yields a heat reduction of about 18 degrees Celsius. Further, in this example, a metal plate was not used on the second housing portion.

In various embodiments, thermal transfer assemblies are preferably sized and installed to avoid simultaneous contact with both heat source components and other electronic components within a marine electronic device. It will be appreciated that, if that were to occur, electrical short circuits may occur. Thus, in some cases, such as that described above, a heat spreader 282 may prevent such contact. In other cases, the thermal transfer assembly may be dimensioned and/or shaped in order to avoid such contact.

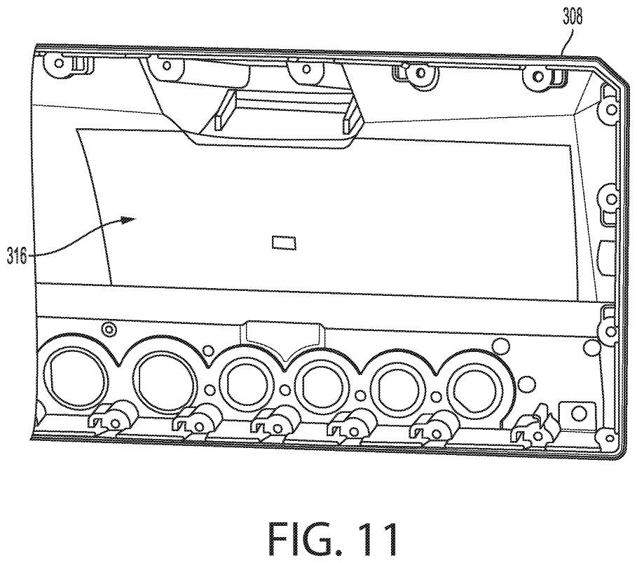

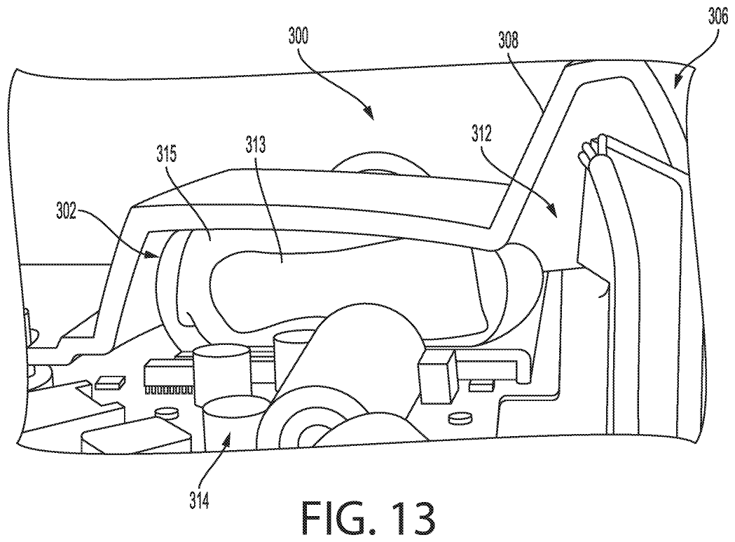

FIGS. 11-13 illustrate a marine electronic device 300 comprising a thermal transfer assembly 302 in accordance with another embodiment of the invention. As with certain marine electronic devices described above, marine electronic device 300 comprises a housing 306 comprising a first housing portion 308 and a second housing portion 310 that together define an enclosed space 312 (FIG. 13). Various electronic components 314 are coupled with second housing portion 310, and in a manner analogous to certain embodiments described above, thermal transfer assembly 302 is disposed on a heat source component, in this example, a heat spreader analogous to heat spreader 282 described above. Also, in this embodiment, thermal transfer assembly 302 comprises a substrate comprising a first foam material 313 that is surrounded by a second foam material 315. Foam material 315, which may be a foam rated for operation at higher temperatures (e.g., those higher than the temperature the heat source component reaches during operation) and which may be more compliant, may be wrapped around foam material 313, which may be a foam that is not rated for use at high temperatures and which may be less compliant.

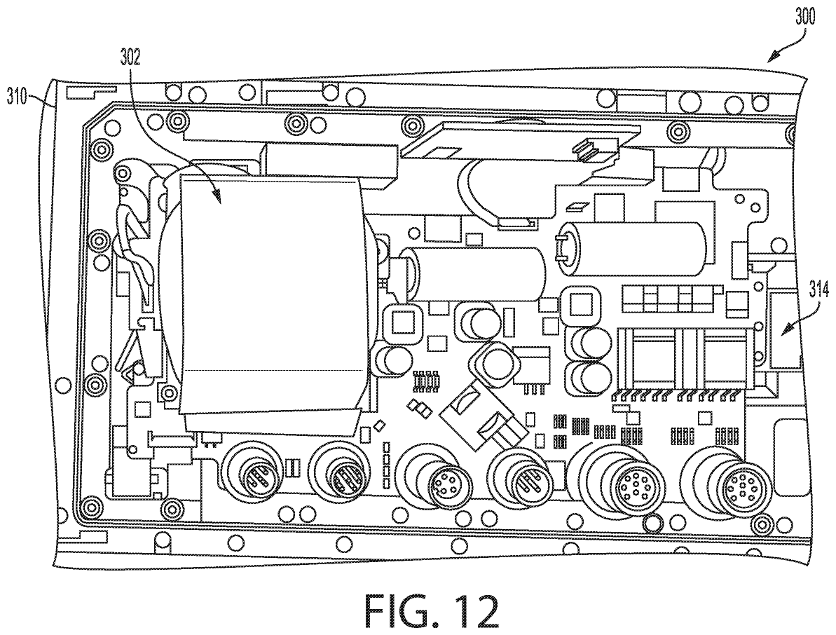

In this embodiment, and with particular reference to FIG. 11, one or more thermal transfer materials 316 may be coupled with first housing portion 308. More particularly, in this embodiment thermal transfer material 316 may comprise a graphite sheet that is disposed on an interior surface of first housing portion 308 via a suitable adhesive. As shown in FIG. 13, when first and second housing portions 308, 310 are coupled together, thermal transfer assembly 302 is compressed and pressed against thermal transfer material 316. Thus, in use, thermal transfer material 316 is disposed between thermal transfer assembly 302 and first housing portion 308. Referring also to FIG. 12, it is seen that the area of thermal transfer material 316 is greater than the area of thermal transfer assembly 302 that would otherwise come into contact with first housing portion 308. Those of skill in the art will appreciate that this allows heat to be transferred or spread over a greater area of first housing portion 308, allowing more heat to be dissipated from the heat source component.

As noted above, the implementation of a thermal transfer assembly within an electronic device will differ in various embodiments, depending among other things on the type of electronic device at issue, the design of its electronic components, and the design of its housing. By way of example, in some marine electronic devices, the printed circuit board has a larger processor and a housing portion may be closer to the processor. Depending on the shape of the housing portion, different configurations of thermal transfer assemblies may be used.

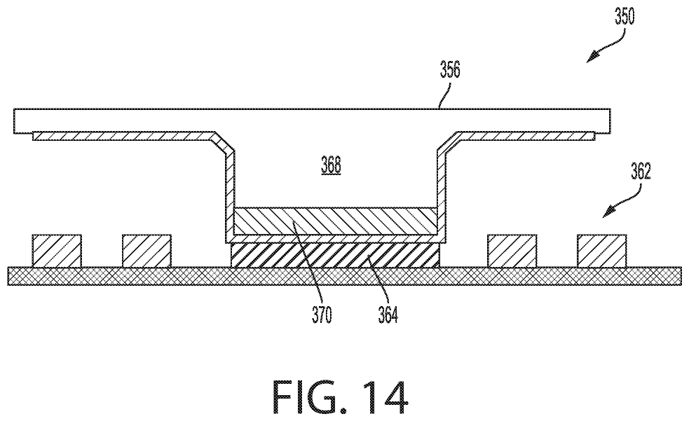

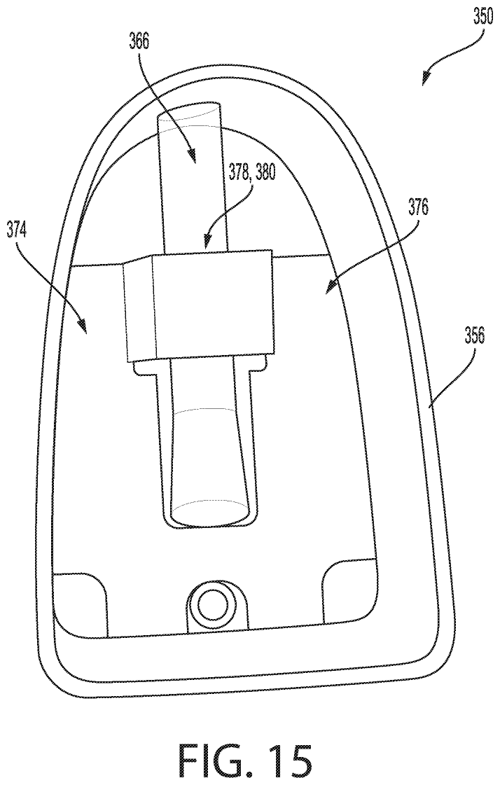

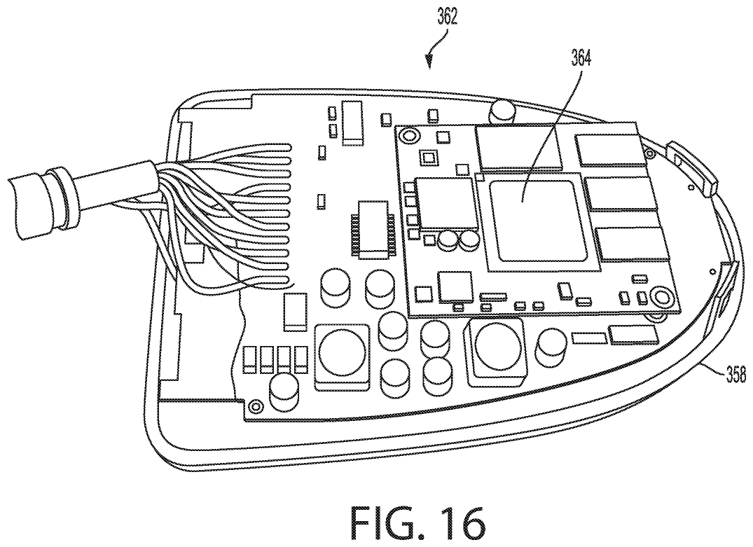

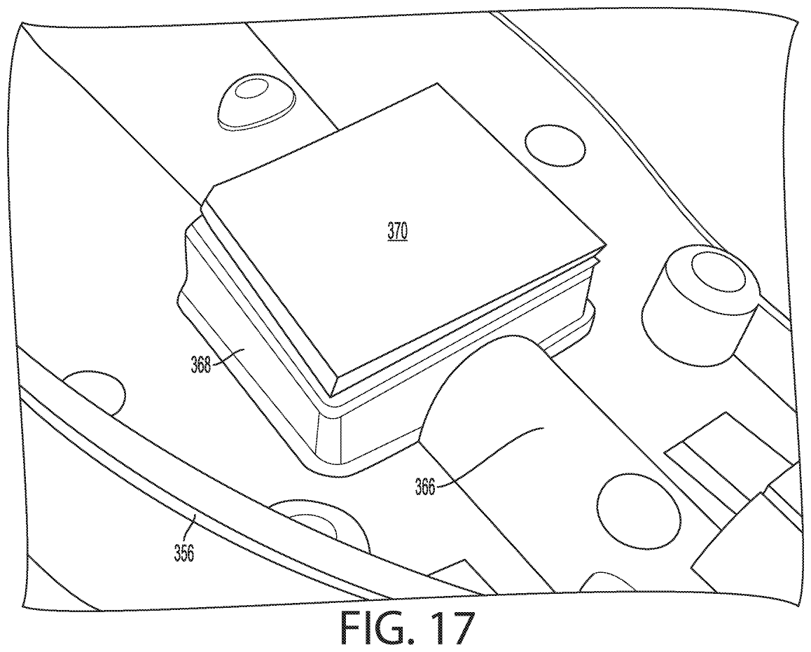

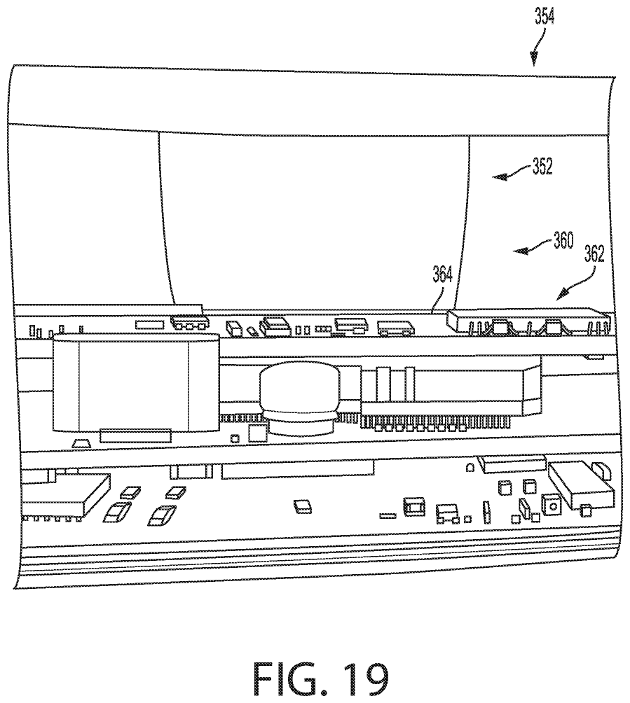

In this regard, FIGS. 14-19 illustrate a marine electronic device 350 comprising a thermal transfer assembly 352 in accordance with other embodiments of the present invention. Again, and analogous to certain marine electronic devices described above, marine electronic device 350 comprises a housing 354 comprising a first housing portion 356 (FIG. 15) and a second housing portion 358 (FIG. 16) that together define an enclosed space 360 (FIG. 19). Various electronic components 362 are coupled with second housing portion 358, including a processor 364. In the illustrated embodiment, marine electronic device 350 may comprise a sonar transducer assembly.

As shown in FIGS. 14, 15, and 17, first housing portion 356 in this embodiment defines a longitudinal ridge 366 that is disposed over processor 364 when first and second housing portions 356, 358 are coupled together. As shown in FIG. 17, a platform 368 may be defined (e.g., during manufacture or later fashioned out of a suitable material, such as a plastic resin) across a portion of ridge 366 to facilitate placement of a substrate 370 of thermal transfer assembly 352. In this embodiment, the platform is defined along ridge 366 in a location that disposes substrate 370 directly over processor 364 when first and second housing portions 356, 358 are coupled together. In one embodiment, substrate 370 may have a height dimension that is greater than the distance between the platform 368 and processor 364, such that substrate 370 may be compressed during use, but this is not required. Also, in other embodiments, platform 366 is not required, and substrate 370 of thermal transfer assembly 352 may be held in place via longitudinal ridge 366 or another feature of the housing.

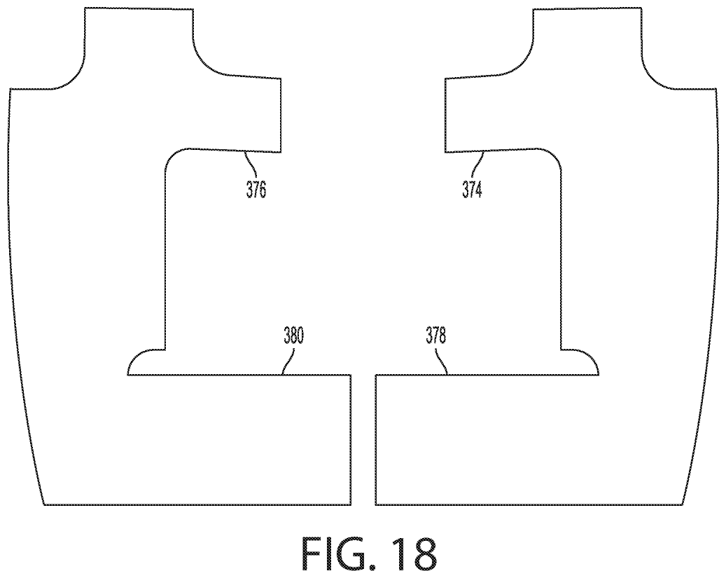

Referring also to FIG. 18, a thermal transfer material 372 of thermal transfer assembly 352 may comprise two graphite sheets 374, 376. As shown, graphite sheets 374, 376 may be shaped such that they conform to a larger area of interior surface of first housing portion 356 than that defined by ridge 366 (see FIG. 15), and they may be coupled with second housing portion 356 using a suitable adhesive, such as an adhesive layer of sheets 374, 376. However, each sheet 374, 376 may define a respective tab 378, 380 that may overlap on substrate 370. Thereby, when first and second housing portions 356, 358 are coupled together, thermal transfer material 372 of thermal transfer assembly 352 may contact processor 364, providing a thermally conductive path from processor 364 to the second housing portion 356.

In one embodiment of a marine electronic device analogous to that described with reference to FIGS. 14-19, performance characteristics again demonstrate several advantages over the prior art. In one example, the substrate 370 has dimensions of about 22 mm×22 mm×2 mm, and thermal transfer material 372 is two graphite sheets each having a thickness of 45 micrometers. The processor 364 generates approximately 10 W during operation. Notably, thermal transfer assembly 352 yields a heat reduction of about 23 degrees Celsius.

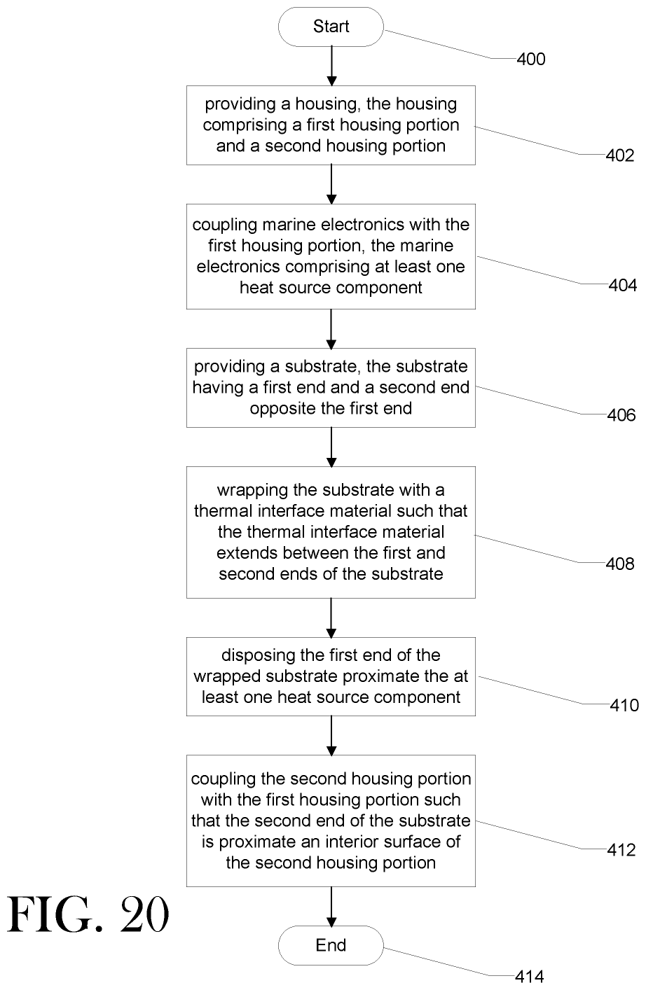

Embodiments of the present invention also provide methods for manufacturing and/or assembly thermal transfer assemblies and marine electronic devices. Various examples of the methods performed in accordance with embodiments of the present invention will now be provided with reference to FIG. 20.

At operation 400, the process starts, and at operation 402, a housing is provided. In various embodiments, the housing may comprise a first housing portion and a second housing portion that are operative to be releasably coupled together. Next, marine electronics are coupled with the first housing portion (operation 404). The marine electronics may comprise at least one heat source component. A substrate also is provided, and the substrate has a first end and a second end opposite the first end (operation 406). At operation 408, the substrate is wrapped with a thermal transfer material such that the thermal transfer material extends between the first and second ends of the substrate. At operation 410, the first end of the wrapped substrate is disposed proximate the at least one heat source component. Then, at operation 412, the second housing portion is coupled with the first housing portion such that the second end of the substrate is proximate an interior surface of the second housing portion. At operation 414, the process ends.

Based on the foregoing, it will be appreciated that embodiments of the invention provide improved systems and methods for dissipating heat from heat source components of a marine electronic device. Many modifications and other embodiments of the inventions set forth herein will come to mind to one skilled in the art to which these inventions pertain having the benefit of the teachings presented in the foregoing descriptions and the associated drawings. Therefore, it is to be understood that the inventions are not to be limited to the specific embodiments disclosed and that modifications and other embodiments are intended to be included within the scope of the appended claims. Moreover, although the foregoing descriptions and the associated drawings describe exemplary embodiments in the context of certain exemplary combinations of elements and/or functions, it should be appreciated that different combinations of elements and/or functions may be provided by alternative embodiments without departing from the scope of the appended claims. In this regard, for example, different combinations of elements and/or functions than those explicitly described above are also contemplated as may be set forth in some of the appended claims. In cases where advantages, benefits or solutions to problems are described herein, it should be appreciated that such advantages, benefits and/or solutions may be applicable to some example embodiments, but not necessarily all example embodiments. Thus, any advantages, benefits or solutions described herein should not be thought of as being critical, required or essential to all embodiments or to that which is claimed herein. Although specific terms are employed herein, they are used in a generic and descriptive sense only and not for purposes of limitation.

What is claimed is:

1. A thermal transfer assembly for a marine electronic device, comprising:
a substrate, the substrate having a top surface, a bottom surface, and at least one side surface extending between the top surface and the bottom surface, wherein the substrate comprises a foam material;
a thermal transfer material comprising at least one layer, the at least one layer comprising graphite;
wherein the thermal transfer material further comprises a first portion and a second portion spaced apart from the first portion, the first portion coupled with the substrate top surface and the second portion coupled with the substrate bottom surface; and
a thermally conductive path along the thermal transfer material between the first portion and the second portion.

2. The thermal transfer assembly of claim 1, wherein the thermal transfer material comprises at least one graphite sheet.

3. The thermal transfer assembly of claim 1, wherein the substrate defines a cuboid shape.

4. The thermal transfer assembly of claim 1, wherein the substrate comprises two foam blocks.

5. The thermal transfer assembly of claim 1, wherein the thermal transfer material is not connected with the at least one side surface of the substrate.

6. The thermal transfer assembly of claim 5, wherein the substrate is wrapped with the thermal transfer material.

7. A marine electronic device, comprising:
a housing, the housing comprising a first housing portion and a second housing portion, the second housing portion releasably coupled with the first housing portion to define an enclosed space therein;
marine electronics disposed within the enclosed space, the marine electronics disposed on a circuit board and comprising at least one heat source component, the at least one heat source component being spaced apart from the second housing portion by a first distance;
a substrate disposed between the at least one heat source component and the second housing portion, the substrate comprising a first surface proximate the at least one heat source component and a second surface proximate the second housing portion; and
a thermally-conductive path extending along a first thermal transfer material having a first portion and a second portion, the first portion disposed between the first surface of the substrate and the at least one heat source component, and the second portion disposed against an interior surface of the second housing portion.

8. The marine electronic device of claim 7, wherein the substrate is compressible, and wherein the substrate defines a thickness that is greater than the first distance.

9. The marine electronic device of claim 8, wherein the substrate comprises a foam.

10. The marine electronic device of claim 7, further comprising a second thermal transfer material disposed on an interior surface of the second housing portion between the first thermal transfer material and the second housing portion.

11. The marine electronic device of claim 7, wherein the at least one heat source component comprises a processor.

12. The marine electronic device of claim 11, further comprising a heat spreader disposed between the at least one heat source component and the first portion of the first thermal transfer material.

13. The marine electronic device of claim 7, wherein the second portion of the first thermal transfer material is coupled with the second surface of the substrate.

14. The marine electronic device of claim 7, wherein the first thermal transfer material comprises graphite.

15. A method of assembling a marine electronic device, the method comprising the steps of:
providing a housing, the housing comprising a first housing portion and a second housing portion;
coupling marine electronics with the first housing portion, the marine electronics comprising at least one heat source component;
providing a substrate, the substrate having a first end and a second end opposite the first end;
wrapping the substrate with a thermal transfer material such that the thermal transfer material extends between the first and second ends of the substrate; and
disposing the first end of the wrapped substrate proximate the at least one heat source component; and
coupling the second housing portion with the first housing portion such that the second end of the substrate is proximate an interior surface of the second housing portion.

16. The method of claim 15, further comprising the step of applying pressure to the thermal transfer material to hold it in place against the heat source component and the interior surface of the second housing portion.

17. The method of claim 16, wherein the thermal transfer material is coupled with the first and second ends of the substrate via an adhesive.

18. The method of claim 17, wherein the substrate comprises a body extending between the first and second ends of the substrate and wherein the thermal transfer material is not adhered to the body.

19. The method of claim 15, wherein the thermal transfer material has an in-plane thermal conductivity greater than about 100 W/m-K.

20. The method of claim 15, wherein the step of wrapping the substrate with a thermal transfer material further comprises the step of coupling at least two sheets of thermal transfer material together.
